(19) United States
(12) Patent Application Publication
(10) Pub. No.: US 2024/0334769 A1
(43) Pub. Date: Oct. 3, 2024

(54) SEMICONDUCTOR DEVICE, DISPLAY DEVICE, PHOTOELECTRIC CONVERSION DEVICE, ELECTRONIC APPARATUS, ILLUMINATION DEVICE, MOVING BODY, AND METHOD OF MANUFACTURING SEMICONDUCTOR DEVICE

(71) Applicant: CANON KABUSHIKI KAISHA, Tokyo (JP)

(72) Inventors: TOSHIHIRO SHOYAMA, Kanagawa (JP); KENTARO SUZUKI, Kanagawa (JP)

(21) Appl. No.: 18/613,434

(22) Filed: Mar. 22, 2024

(30) Foreign Application Priority Data
Mar. 30, 2023 (JP) 2023-056358

(51) Int. Cl. H10K 59/131; H10K 59/12; H10K 59/80

(52) U.S. Cl. CPC H10K 59/131; H10K 59/1201; H10K 59/878

(57) ABSTRACT

A semiconductor device is provided. The semiconductor device includes: a substrate; a pad used to connect an external terminal; an interlayer insulating film, which is arranged between a main surface of the substrate and the pad and where a wiring pattern is arranged; and an insulating film arranged so as to cover a peripheral portion of the pad. An opening portion configured to connect the pad to the external terminal is provided in the insulating film, the pad and the wiring pattern are electrically connected via a plug in contact with both the pad and the wiring pattern, and in an orthogonal projection with respect to the main surface, the plug is arranged outside the opening portion.

### BACKGROUND OF THE INVENTION

### Field of the Invention

The present invention relates to a semiconductor device, a display device, a photoelectric conversion device, an electronic apparatus, an illumination device, a moving body, and a method of manufacturing the semiconductor device.

### Description of the Related Art

In a semiconductor device, as the number of input/output terminals increases or the chip area decreases, a bonding pad (to be sometimes simply referred to as a pad hereinafter) connecting a chip and an external apparatus is reduced in size. If the pad is reduced in size, when connecting an external connection terminal to the pad via an anisotropic conductive film or the like, a local pressure is applied, and a crack may occur in the chip. Japanese Patent Laid-Open No. 2010-145579 describes that, in order to increase the strength of a pad, a plug, whose upper end is arranged at a higher position than the lower end face of the pad, is arranged in an insulating film in contact with the pad.

### SUMMARY OF THE INVENTION

With the arrangement described in Japanese Patent Laid-Open No. 2010-145579, when a pressure for connecting the external connection terminal to the pad is applied, a crack can occur in the insulating film due to an elasticity difference between the material of the plug and the material of the insulating film, and the reliability of the semiconductor device can be deteriorated.

Some embodiments of the present invention provide a technique advantageous in improving the reliability of a semiconductor device.

According to some embodiments, a semiconductor device comprising: a substrate; a pad used to connect an external terminal; an interlayer insulating film, which is arranged between a main surface of the substrate and the pad and where a wiring pattern is arranged; and an insulating film arranged so as to cover a peripheral portion of the pad, wherein an opening portion configured to connect the pad to the external terminal is provided in the insulating film, the pad and the wiring pattern are electrically connected via a plug in contact with both the pad and the wiring pattern, and in an orthogonal projection with respect to the main surface, the plug is arranged outside the opening portion, is provided.

According to some other embodiments, a method of manufacturing a semiconductor device comprising: a substrate; a pad used to connect an external terminal; an interlayer insulating film, which is arranged between a main surface of the substrate and the pad and where a wiring pattern is arranged; and an insulating film arranged so as to cover a peripheral portion of the pad, wherein the pad and the wiring pattern are electrically connected via a plug in contact with both the pad and the wiring pattern, the method comprises providing, in the insulating film, an opening portion configured to connect the pad to the external terminal, and in an orthogonal projection with respect to the main surface, the plug is arranged outside the opening portion, is provided.

Further features of the present invention will become apparent from the following description of exemplary embodiments (with reference to the attached drawings).

### BRIEF DESCRIPTION OF THE DRAWINGS

FIG. 1 is a view showing an example of the arrangement of a semiconductor device according to an embodiment;

FIGS. 2A and 2B are views showing an example of a method of manufacturing the semiconductor device shown in FIG. 1;

FIGS. 3A and 3B are views showing the example of the method of manufacturing the semiconductor device shown in FIG. 1;

FIGS. 4A and 4B are views showing the example of the method of manufacturing the semiconductor device shown in FIG. 1;

FIGS. 5A and 5B are views showing the example of the method of manufacturing the semiconductor device shown in FIG. 1;

FIGS. 6A and 6B are views showing the example of the method of manufacturing the semiconductor device shown in FIG. 1;

FIGS. 7A and 7B are views showing the example of the method of manufacturing the semiconductor device shown in FIG. 1;

FIGS. 8A and 8B are views showing the example of the method of manufacturing the semiconductor device shown in FIG. 1;

FIG. 9 is a view showing the example of the method of manufacturing the semiconductor device shown in FIG. 1;

FIGS. 10A and 10B are sectional views showing an example of the arrangement of the pixel of the semiconductor device according to the embodiment;

FIGS. 11A to 11C are views showing an example of an image forming device using the semiconductor device according to the embodiment;

FIG. 12 is a view showing an example of a display device using the semiconductor device according to the embodiment;

FIG. 13 is a view showing an example of a photoelectric conversion device using the semiconductor device according to the embodiment;

FIG. 14 is a view showing an example of an electronic apparatus using the semiconductor device according to the embodiment;

FIGS. 15A and 15B are views each showing an example of a display device using the semiconductor device according to the embodiment;

FIG. 16 is a view showing an example of an illumination device using the semiconductor device according to the embodiment;

FIG. 17 is a view showing an example of a moving body using the semiconductor device according to the embodiment; and

FIGS. 18A and 18B are views each showing an example of a wearable device using the semiconductor device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

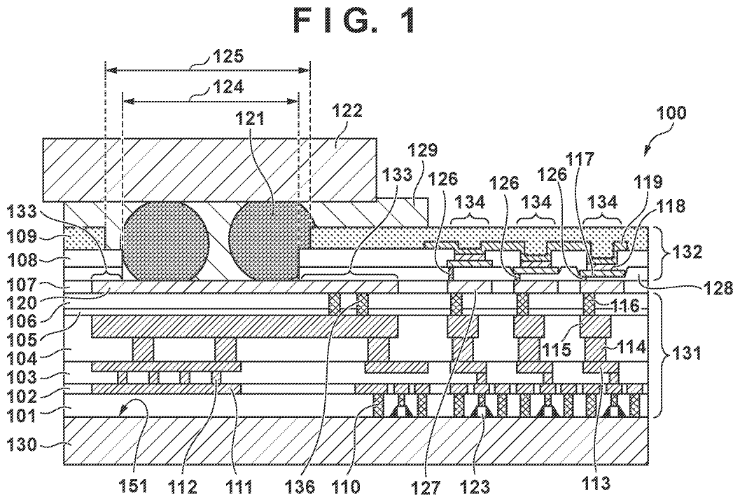

With reference to FIGS. 1 to 9, a semiconductor device according to an embodiment of the present disclosure will be described. In the embodiment to be described below, a description will be given while taking a light emitting device as an example of the semiconductor device. However, the present disclosure is not limited to this, and the present disclosure is applicable to a processing device, a storage device, a photoelectric conversion device, and the like, each including a semiconductor element, of various logic circuits, storage circuits, pixel circuits, and the like. More specifically, the present disclosure is applicable to all semiconductor devices to be described below, each of which includes an external connection pad and a plug in contact with the pad.

FIG. 1 is a view showing an example of the arrangement of a light emitting device 100 as an example of the semiconductor device in this embodiment. FIG. 1 shows a section including a pixel portion where pixels 134 of the light emitting device 100 are arranged, and a pad portion for electrically connecting the outside of the light emitting device 100 to the light emitting device 100.

The light emitting device 100 includes a substrate 130, a pad 120 for connecting an external terminal 122, an interlayer insulating film 131, which is arranged between a main surface 151 of the substrate 130 and the pad 120 and where wiring patterns 111, 113, and 115 are arranged, and an insulating film 132 arranged so as to cover a peripheral portion 133 of the pad 120. The light emitting device 100 also includes a plurality of pixels 134 arranged on the main surface 151 of the substrate 130 and each including a light emitting layer 118. The light emitting device 100 further includes a plurality of transistors 123 arranged on the main surface 151 of the substrate 130 to drive the light emitting layer 118 of each of the plurality of pixels 134 arranged in the pixel portion. The pad 120, the transistors 123, an upper electrode 119 and a lower electrode 117 for applying a voltage to the light emitting layer 118, the substrate 130, and the like are interconnected via the wiring patterns 111, 113, and 115, plugs 110, 112, 114, 116, 126, and 136, and the like, as appropriate.

For the substrate 130, for example, single crystal silicon having a thickness of 750 to 800 μm may be used. If the substrate 130 is made of silicon, the thickness of the substrate 130 may be 770 to 780 μm. A transparent conductive material can be used for the upper electrode 119 that extracts light of the light emitting layer 118. In the light emitting device 100 in this embodiment, a transparent conductive material is also used for the lower electrode 117, and each of the plurality of pixels 134 includes, between the light emitting layer 118 and a reflection layer 127 arranged between the light emitting layer 118 and the main surface 151 of the substrate 130, an insulating layer 128 functioning as an optical adjustment layer for adjusting the distance such that light components interfere and strengthen each other. As shown in FIG. 1, the plurality of pixels 134 include pixels different from each other in the thickness of the insulating layer 128 functioning as the optical adjustment layer. The insulating layer 128 functioning as the optical adjustment layer may form a part of the insulating film 132 arranged so as to cover the peripheral portion 133 of the pad 120 and formed by a plurality of insulating layers stacked on each other. For the insulating layer 128 functioning as the optical adjustment layer, an inorganic material such as silicon oxide or silicon nitride may be used, or an organic material such as a resin may be used.

The lower electrode 117 and the reflection layer 127 are connected by the plug 126. The reflection layer 127 and the wiring pattern 115 are connected by the plug 116. An insulating layer 109 for ensuring the light of the light emitting layer 118 (light emitting device 100) is arranged above the light emitting layer 118. The insulating layer 109 can also be called a sealing layer. As shown in FIG. 1, the insulating layer 109 may form a part of the above-described insulating film 132. That is, each of the plurality of pixels 134 may be covered with at least one insulating layer of the plurality of insulating layers forming the insulating film 132. Further, each of the plurality of pixels 134 may be covered with the insulating layer 109 farthest from the main surface 151 of the substrate 130 among the plurality of insulating layers. For the insulating layer 109, a material generally used in a semiconductor device is arbitrarily selected. For example, silicon nitride as a dense light-transmissive film may be used for the insulating layer 109.

Silicon oxide or the like may be used for an insulating layer 108 arranged between the insulating layer 128 and the insulating layer 109. The insulating layer 108 may also form a part of the insulating film 132 together with the insulating layer 109 and the insulating layer 128. In this manner, the insulating film 132 is formed by the plurality of insulating layers 108, 109, and 128 stacked on each other, and the plurality of insulating layers 108, 109, and 128 may include insulating layers containing materials different from each other.

The transistor 123 can be formed using a known semiconductor process technique. A refractory metal such as tungsten can be used for the plug 110. A material such as copper may be used for the wiring patterns 111, 113, and 115 and the plugs 112 and 114, but the material is not limited to this. The wiring patterns 111, 113, and 115 made of aluminum and the plugs 112, and 114 made of tungsten may be used.

The interlayer insulating film 131 arranged between the main surface 151 of the substrate 130 and the wiring layer where the pad 120 is arranged can be formed by a plurality of interlayer insulating layers 101 to 106 stacked on each other. An insulating layer 107 is also arranged in the wiring layer where the pad 120 is arranged. A silicon-based insulating material such as silicon oxide, silicon nitride, or silicon carbide may be used for the interlayer insulating layers 101 to 106 and the insulating layer 107. Alternatively, a Low-k material having a lower dielectric constant than silicon oxide may be used for the interlayer insulating layers 101 to 106 and the insulating layer 107.

A metal material such as aluminum is used for the pad 120 used to electrically connect the light emitting device 100 and the outside of the light emitting device 100. The pad 120 is electrically connected to the wiring pattern 115 using copper or the like by the plug 136 containing a refractory metal such as tungsten. In this manner, the pad 120 and the wiring pattern 115 may contain materials different from each other. Further, the pad 120 and the plug 136 may contain materials different from each other.

In the arrangement shown in FIG. 1, the pad 120 may be formed at the same time as the reflection layer 127. That is, the reflection layer 127 may be a conductive pattern arranged in the same wiring layer as the pad 120. Therefore, the pad 120 and the reflection layer 127 can have almost the same film configuration and film thickness. However, when forming an opening portion 124 in the insulating film 132 to connect the pad 120 to the external terminal 122, the film thickness of the pad 120 in the opening portion 124 can become smaller than those of the peripheral portion 133 and the reflection layer 127. Further, for example, the plug 136 connecting the pad 120 and the wiring pattern 115 may be formed at the same time as the plug 116 connecting the reflection layer 127 and the wiring pattern 115. However, the present disclosure is not limited to this. The pad 120 and the reflection layer 127 may be made of metal materials different from each other, or may be, for example, arranged in layers different from each other.

The peripheral portion 133 of the pad 120 is covered with the insulating film 132. However, the opening portion 124 for connecting the pad 120 to the external terminal 122 is provided in the insulating film 132, and the pad 120 and the external terminal 122 are connected in the opening portion 124. More specifically, the pad 120 is electrically connected to the external terminal 122 via a conductive film 129 arranged in the opening portion 124. The conductive film 129 can be an anisotropic conductive film (ACF) containing conductive particles 121. When the external terminal 122 is pressure-bonded to the pad 120, the conductive film 129 functions as a conductive portion between the pad 120 and the external terminal 122.

When connecting the external terminal 122 to the pad 120, a force to press the external terminal 122 against the pad portion where the pad 120 is arranged is applied. At this time, a load is applied to the interlayer insulating film 131 arranged below the pad portion and the wiring structure including the wiring patterns 111, 113, and 115 and the plugs 112, 114, and 116. If an irretrievable amount of distortion occurs, a crack can occur in the interlayer insulating film 131. If a crack occurs, a defect can occur due to disconnections in the wiring patterns 111, 113, and 115. In addition, there is a concern that the metal forming the wiring structure diffuses into the interlayer insulating film 131 via the crack, resulting in a deterioration in reliability. On the other hand, if the pressing pressure is reduced, poor adhesion can occur between the pad 120 and the external terminal 122. Therefore, there is a demand for a structure in which no crack occurs even if a sufficient pressure is applied to the pad portion when connecting the external terminal 122 to the pad 120.

To prevent occurrence of a defect such as a crack caused by a stress applied to the interlayer insulating film 131 below the pad 120 even when a pressure is applied to connect the external terminal 122 to the pad 120 via the conductive film 129, the plug 136 is arranged outside the opening portion 124 in an orthogonal projection with respect to the main surface 151 of the substrate 130. The plug 136 is a plug which is in contact with both the pad 120 and the wiring pattern 115 and electrically connects the pad 120 and the wiring pattern 115. As shown in FIG. 1, the plurality of wiring layers (the wiring layers where the wiring patterns 111, 113, and 115 are arranged, respectively) including the wiring layer where the wiring pattern 115 is arranged are arranged in the interlayer insulating film 131, and the wiring pattern 115 may be arranged in the wiring layer closest to the pad 120 among the plurality of wiring layers.

Further, the conductive particles 121 in the conductive film 129 come into contact with the insulating film 132, so that a load is also applied to the insulating film 132 arranged around the opening portion 124. Therefore, as has been described above, the insulating film 132 is formed by the plurality of insulating layers 108, 109, and 128 containing materials different from each other to form a structure that diffuses the load. Further, the plug 136 is in contact with the pad 120 in the peripheral portion 133 where the pressure applied when connecting the external terminal 122 to the pad 120 is lower than in the opening portion 124. With this, occurrence of a crack is suppressed. Furthermore, as shown in FIG. 1, the opening portion provided in the insulating film 132 may have a two-stage configuration including the opening portion 124 arranged in the insulating layers 128 and 108 and an opening portion 125 arranged in the insulating layer 109 farther from the pad 120 than the opening portion 124. The opening area of the opening portion can increase as the distance from the pad 120 increases. In the arrangement shown in FIG. 1, the opening portion provided in the insulating film 132 to expose the pad 120 to the conductive film 129 has the two-stage configuration including the opening portion 124 and the opening portion 125, but a configuration of three or more stages may be used, or only the opening portion 124 may be provided.

For the interlayer insulating layers 105 and 106 arranged between the pad 120 and the wiring pattern 115 among the plurality of interlayer insulating layers, a silicon-based material such as silicon oxide or silicon nitride is used. For the plug 136, a refractory metal such as tungsten can be used. In general, a refractory metal is harder than a silicon-based material. Therefore, when a pressure for connecting the external terminal 122 is applied, the interlayer insulating layers 105 and 106 deform more than the plug 136, and thus a distortion occurs. If the distortion exceeds the limit, a crack can occur. Further, if the thickness of the pad 120 is small, for example, if the thickness of the pad 120 is smaller than the thickness of the wiring pattern 115, the pressure upon pressure-bonding is mainly applied to the pad 120 so that the pad 120 is largely deformed. Thus, the interlayer insulating layers 105 and 106 below the pad 120 are easily distorted. Hence, in a case where the plug 136 is formed by containing a refractory metal, a case where the thickness of the pad 120 is small, and the like, the arrangement of the plug 136 shown in FIG. 1 has a larger effect of suppressing occurrence of a crack.

Further, as shown in FIG. 1, the plug 136 may be thinner than the plug 114. As has been described above, the plug 136 is a plug which is in contact with both the pad 120 and the wiring pattern 115 and electrically connects the pad 120 and the wiring pattern 115. The plug 114 is a plug which is in contact with both the wiring pattern 115 and the wiring pattern 113, which is arranged in the wiring layer arranged between the wiring layer where the wiring pattern 115 is arranged and the main surface 151 of the substrate 130, and electrically connects the wiring pattern 115 and the wiring pattern 113. If the plug 136 is thick, when the pressure for connecting the external terminal 122 is applied, the wiring pattern 115 receives a force from the plug 136 and is easily deformed by, for example, being dented or the like. In a case where the plug 136 is formed by containing a refractory metal, a case where the thickness of the pad 120 is smaller than the thickness of the wiring pattern 115, and the like, the wiring pattern 115 receives a load via the plug 136 and can be more easily deformed. The deformation of the wiring pattern 115 causes occurrence of distortions in the interlayer insulating layer 105 and the plug 136, and cracks can occur in the interlayer insulating layers 105 and 106 and the like. To prevent this, deformation of the wiring pattern 115 is suppressed by forming the thin plug 136, for example, forming the plug 136 thinner than the plug 114. As a result, occurrence of a crack is suppressed. Here, when the plug 136 is thinner than the plug 114, this means that, for example, the area of the plug 136 in the orthogonal projection with respect to the main surface 151 of the substrate 130 is smaller than the area of the plug 114 in the orthogonal projection with respect to the main surface 151 of the substrate 130.

It has been described above that, in the arrangement shown in FIG. 1, the pad 120 and the reflection layer 127 have almost the same film configuration and film thickness. In an optical interference structure, the higher the reflectance of the reflection layer 127, the more excellent the light emission efficiency of the light emitting device 100. If the film thickness of the reflection layer 127 increases, the surface roughness increases due to the growth of grains of the metal forming the reflection layer, and the reflectance can be decreased. By using the arrangement of the plug 136 shown in FIG. 1, the film thickness of each of the pad 120 and the reflection layer 127 can be reduced.

The interlayer insulating layers 105 and 106 can contain materials different from each other, such as silicon oxide and silicon nitride. If the interlayer insulating layers 105 and 106 below the pad 120 are formed by containing different materials, since the elastic strengths of the respective materials are different from each other, a crack easily occurs upon receiving a pressure. Accordingly, arranging the plug 136 so as not to be in contact with the pad 120 below the opening portion 124 as shown in FIG. 1 is effective in suppressing a crack.

As shown in FIG. 1, in the orthogonal projection with respect to the main surface 151 of the substrate 130, the external terminal 122 can include a portion overlapping the plug 136. Further, in the orthogonal projection with respect to the main surface 151 of the substrate 130, the conductive film 129 can include a portion in contact with the insulating film 132 outside the opening portion 124. On the other hand, the conductive particles 121 in the conductive film 129 can exist not only inside the opening portion 124 but also outside the opening portion 124. Even in a case where the conductive particles 121 exist above the plug 136, since the insulating layers 108, 109, and 128 function as a buffer layer as has been described above, an effect of suppressing a crack can be obtained. As a result, even in a region covered with the external terminal 122, the plug 136 can be arranged below the insulating layers 108, 109, and 128. Thus, the area of the pad portion where the pad 120 is arranged can be reduced, and the chip size can be reduced.

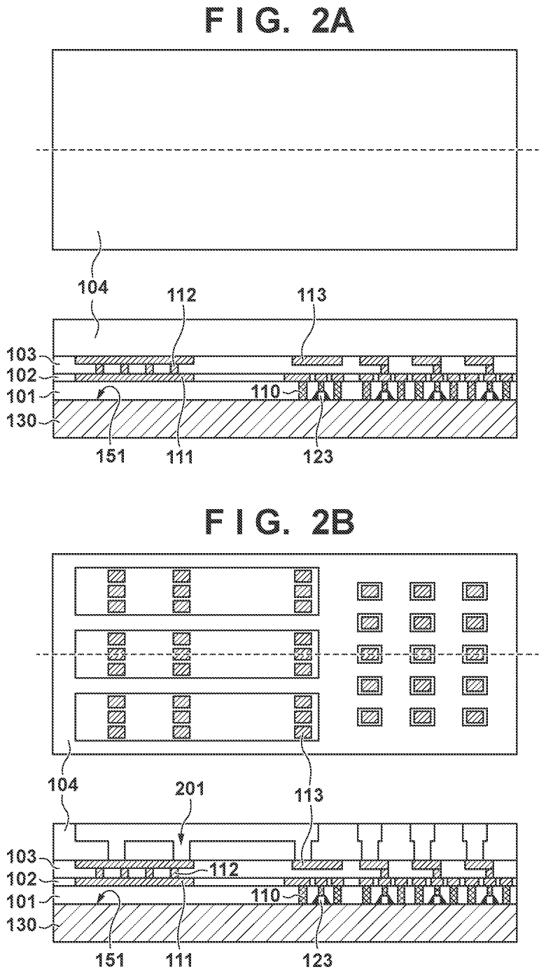

With reference to FIGS. 2A to 9, a method of manufacturing the light emitting device 100 according to this embodiment will be described below. In each drawing, the arrangement viewed from above is shown on the upper side, and a section taken along a dashed line in a central portion viewed from above is shown on the lower side.

First, as shown in FIG. 2A, by using a known semiconductor process technique, the transistors 123, the plugs 110, the wiring patterns 111 and 113, the plugs 112, the interlayer insulating layers 101 to 104, and the like are formed on the main surface 151 of the substrate 130. As has been described above, a refractory metal such as tungsten can be used for the plug 110. For the wiring patterns 111 and 113, the plugs 112, and the like, copper, aluminum, or the like may be used. For the interlayer insulating layers 101 to 104, silicon oxide, silicon nitride, silicon oxynitride, silicon carbide, or the like may be used. A barrier metal layer using titanium or an oxide thereof, tantalum or a nitride thereof, or the like may be arranged at the interfaces of the interlayer insulating layers 101 to 104 with the wiring patterns 111 and 113 and the plugs 112. In order to maintain the flatness of each of the interlayer insulating layers 101 to 104, a planarization process using a chemical mechanical polishing (CMP) method or the like may be performed, as appropriate.

After the interlayer insulating layer 104 is formed, as shown in FIG. 2B, openings 201 are provided in the interlayer insulating layer 104 by using a photolithography method, a dry etching method, or the like. At this time, the opening 201 may be provided even between the substrate 130 and a portion where the pad 120 is to be arranged in a subsequent step.

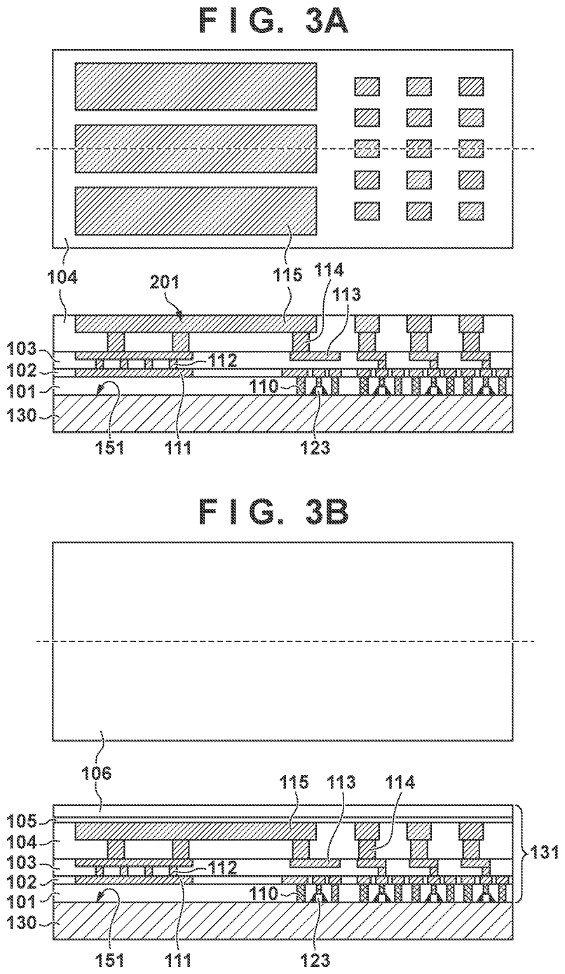

Then, as shown in FIG. 3A, the plugs 114 and the wiring pattern 115 are formed by, for example, forming a metal material such as copper in the openings 201 provided in the interlayer insulating layer 104 by using a plating method, and planarizing the metal material by using a CMP method. Here, the plugs 114 and wiring pattern 115 using a dual damascene structure are exemplified, but the present disclosure is not limited to this. The plugs 114 and the wiring pattern 115 may be formed, as appropriate, using a known semiconductor process technique.

After the plugs 114 and the wiring pattern 115 are formed, as shown in FIG. 3B, the interlayer insulating layers 105 and 106 are deposited. For example, silicon nitride, silicon carbide, or the like may be used as the interlayer insulating layer 105, and silicon oxide or the like may be used as the interlayer insulating layer 106. However, the present disclosure is not limited to this, and other insulating materials may be used as the interlayer insulating layers 105 and 106. The interlayer insulating layers 101 to 106 form the interlayer insulating film 131. In this embodiment, two interlayer insulating layers 105 and 106 are arranged between the pad 120 and the wiring pattern 115 among the plurality of interlayer insulating layers 101 to 106, but three or more interlayer insulating layers may be arranged therebetween. In that case, the respective interlayer insulating layers may contain material different from each other. Alternatively, the interlayer insulating layers containing materials different from each other and the interlayer insulating layers made of the same material may be mixed.

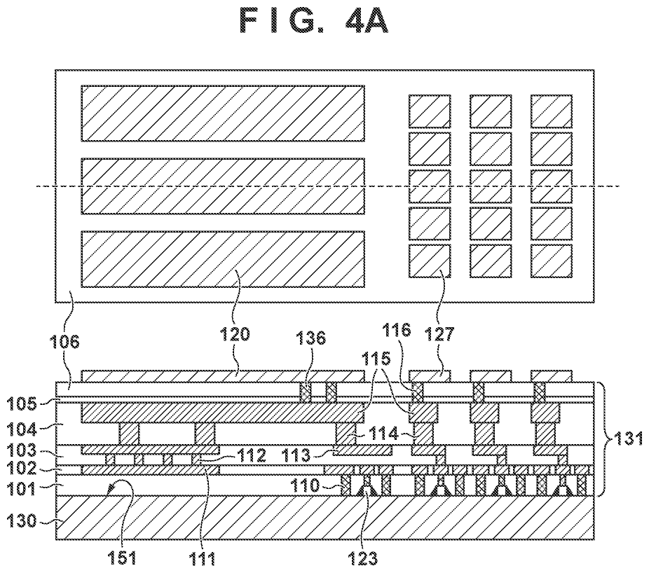

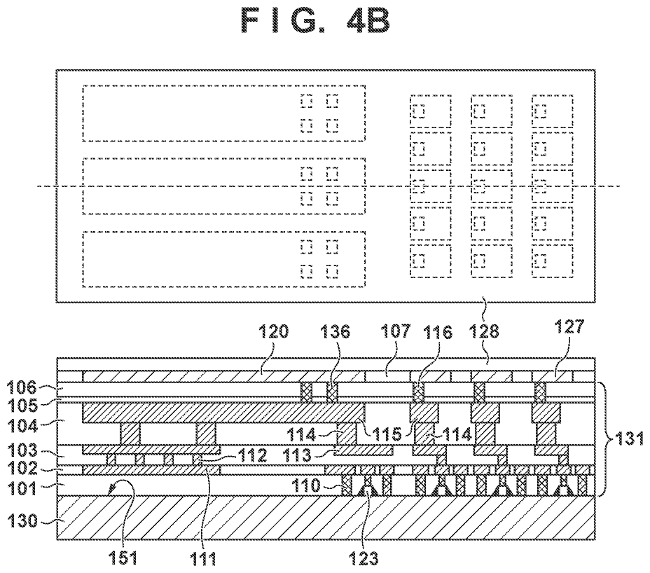

As shown in FIG. 4A, the plugs 116 and 136 are formed in the interlayer insulating layer 106, and then the pad 120 and the reflection layer 127 are formed on the interlayer insulating layer 106. As has been described above, the plug 136 is arranged in a region which does not overlap the opening portion 124 of the insulating film 132 to be formed in a subsequent step. A refractory metal material such as tungsten can be used as the materials of the plugs 116 and 136. The pad 120 and the reflection layer 127 can be formed by depositing a material such as aluminum by using a known photolithography method, dry etching method, or the like. In this embodiment, an example is shown in which the pad 120 and the reflection layer 127 are simultaneously formed using the same material. However, the present disclosure is not limited to this, and the pad 120 and the reflection layer 127 may be formed using different materials, or may be formed in different layers.

After the pad 120 and the reflection layer 127 are formed, as shown in FIG. 4B, the insulating layer 107 is formed. The insulating layer 107 can be formed using a CMP method, an etch back method, or the like after depositing an insulating material. The insulating layer 128 which also functions as an optical adjustment layer is deposited on the insulating layer 107.

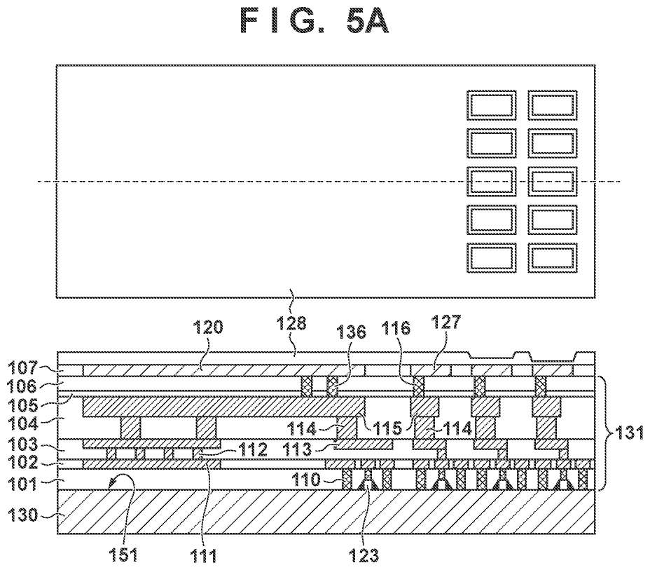

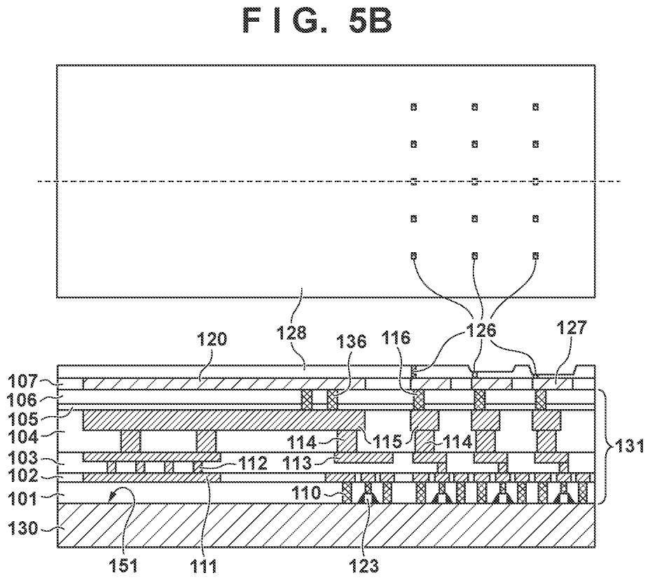

After the insulating layer 128 is formed, as shown in FIG. 5A, the optical adjustment layer is formed by adjusting the thickness of the insulating layer 128 on the reflection layer 127 in accordance with the light emission colors of the pixels 134. Adjustment of the thickness of the insulating layer 128 can be implemented using a photolithography method, a dry etching method, or the like.

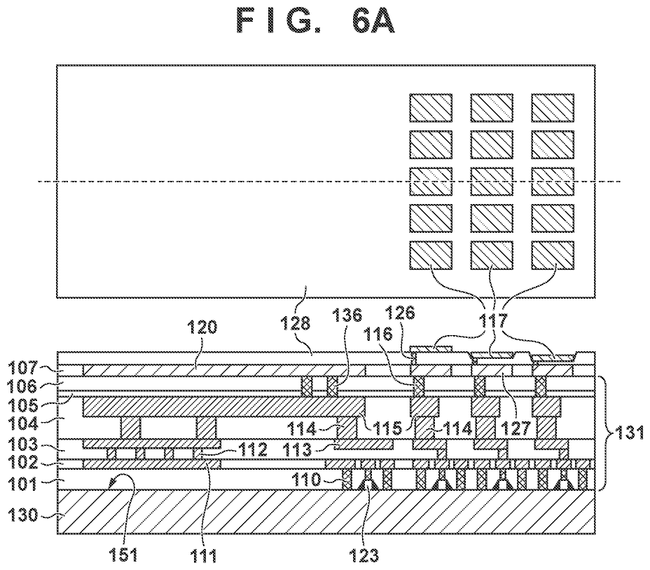

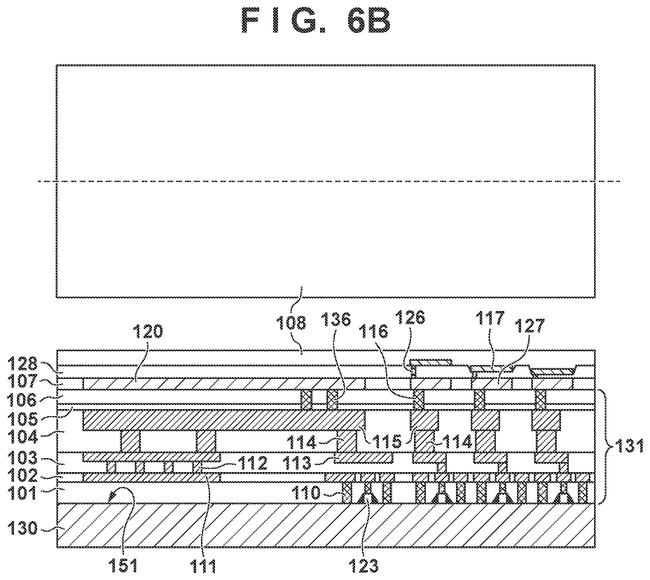

After the thickness of the insulating layer 128 is adjusted, as shown in FIG. 5B, the plugs 126 are formed. After the plugs 126 are formed, as shown in FIG. 6A, the lower electrodes 117 are formed. Then, as shown in FIG. 6B, the insulating layer 108 is formed. In order to prevent unevenness in the surface of the insulating layer 108 caused by the lower electrodes 117 and steps functioning as the optical adjustment layer formed in the insulating layer 128, the insulating layer 108 may be planarized using a CMP method or the like after depositing an insulating material.

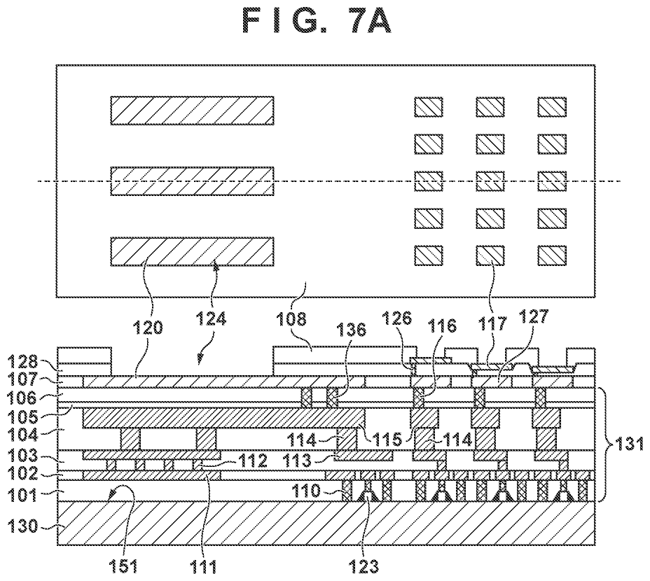

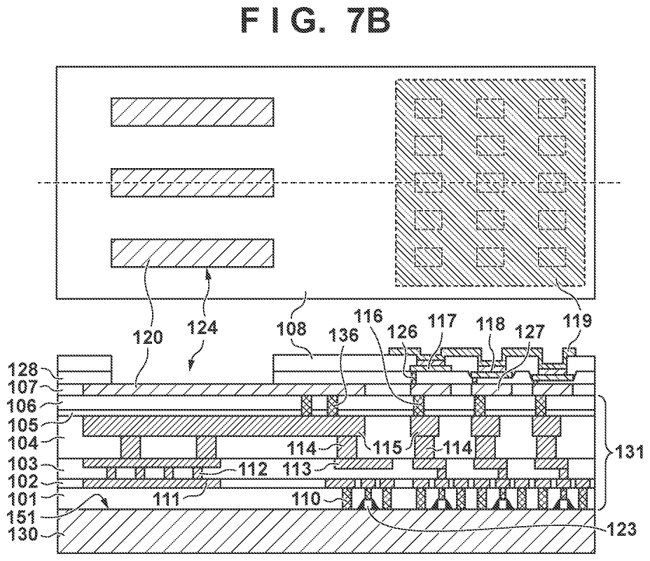

Then, as shown in FIG. 7A, opening portions are formed in the insulating layers 108 and 128 by using a photolithography method, a dry etching method, or the like, to expose the pad 120 and the lower electrodes 117. In a step shown in FIG. 7A, the opening portion to expose the pad 120 becomes the opening potion 124. As has been described above, in the orthogonal projection with respect to the main surface 151 of the substrate 130, the plug 136 connecting the pad 120 and the wiring pattern 115 is arranged outside the opening portion 124.

In the portion where the lower electrode 117 is exposed, the light emitting layer 118 and the upper electrode 119 are formed as shown in FIG. 7B. Each of the light emitting layer 118 and the upper electrode 119 may be formed by, for example, using a vacuum deposition method and a metal mask. By using the metal mask, the process can be simplified as compared to a case of using a photolithography method or an etching method. Further, in the arrangement shown in FIG. 7B, the light emitting layer 118 is patterned for each pixel 134 (lower electrode 117), but the light emitting layer 118 may be shared by the plurality of pixels 134 (lower electrodes 117), similar to the upper electrode 119.

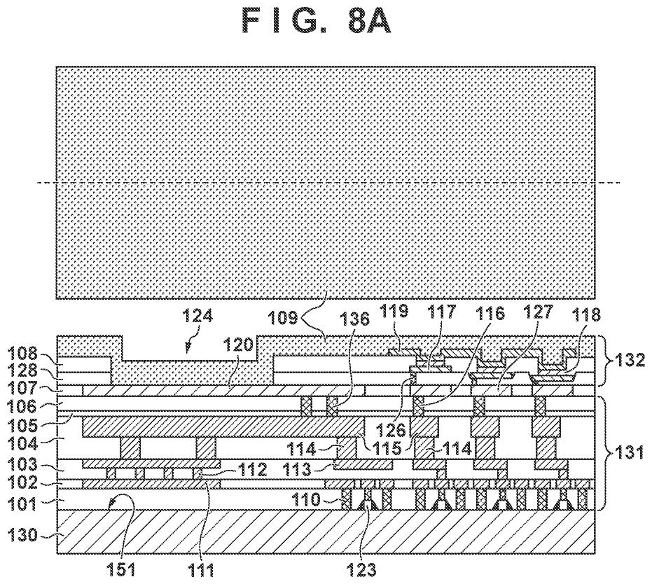

Then, as shown in FIG. 8A, the insulating layer 109, which can function as a sealing layer, is deposited so as to cover the upper electrode 119 and the pad 120. The material of the insulating layer 109 can be arbitrarily selected from materials generally used in a semiconductor device. For the insulating layer 109, for example, silicon nitride as a dense light-transmissive film may be used.

After the insulating layer 109 is deposited, as shown in FIG. 8B, the opening portion 125 is provided so as to expose the pad 120. The opening portion 125 may be provided larger than the opening portion 124. By using the steps as described above, the light emitting device 100 according to this embodiment can be manufactured. However, it is needless to say that various other steps used in a semiconductor process technique may be added and each step can be modified.

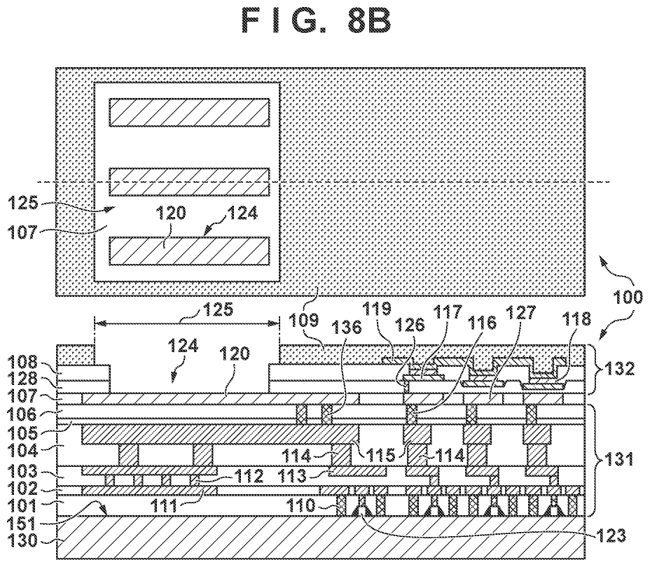

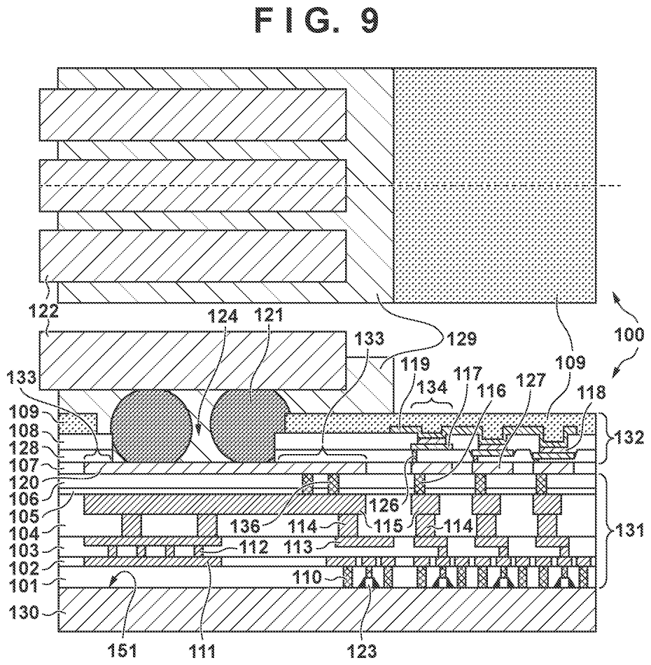

As shown in FIG. 9, the external terminal 122 is connected to the pad 120 of the light emitting device 100 via the conductive film 129 including the conductive particles 121. Connection via the conductive film 129 as the ACF enables electrical connection in the vertical direction, in which the necessary pressure for connection is applied, while maintaining the insulation in a direction intersecting the direction in which the pressure is applied. Connection via the conductive film 129 is widely used in the light emitting device 100 in which multiple small pads 120 are connected to the external terminal 122. As in the arrangement shown in FIG. 9, the conductive film 129 can be arranged between the external terminals 122, but the insulation in the arrangement direction of the external terminals 122, which intersects the direction in which a pressure is applied during connection, is maintained, and the pad 120 and the external terminal 122 are electrically connected.

When connecting the pad 120 to the external terminal 122, the external terminal 122 is pressed against the pad portion where the pad 120 is arranged. In this case, in the light emitting device 100 according to this embodiment, the plug 136 in contact with both the pad 120 and the wiring pattern 115 is not arranged at the position overlapping the opening portion 124. Therefore, occurrence of cracks in the interlayer insulating layers 105 and 106 is suppressed, and this suppresses a deterioration in reliability caused by a defect due to disconnection of the wiring pattern 115 and diffusion of the metal contained in the wiring pattern 115 via the cracks. In addition, the insulating film 132 covering the peripheral portion 133 of the pad 120 is formed by the insulating layers containing multiple different materials, such as the insulating layer 128 functioning as the optical adjustment layer, the insulating layer 108 between the lower electrode 117 and the upper electrode 119 in the pixel 134, and the insulating layer 109 functioning as the sealing layer. With this, even if the conductive particle 121 come into contact with a portion of the insulating film 132 which overlaps the peripheral portion 133 of the pad 120, the interlayer insulting layers 105 and 106 where the plug 136 is arranged can be sufficiently protected.

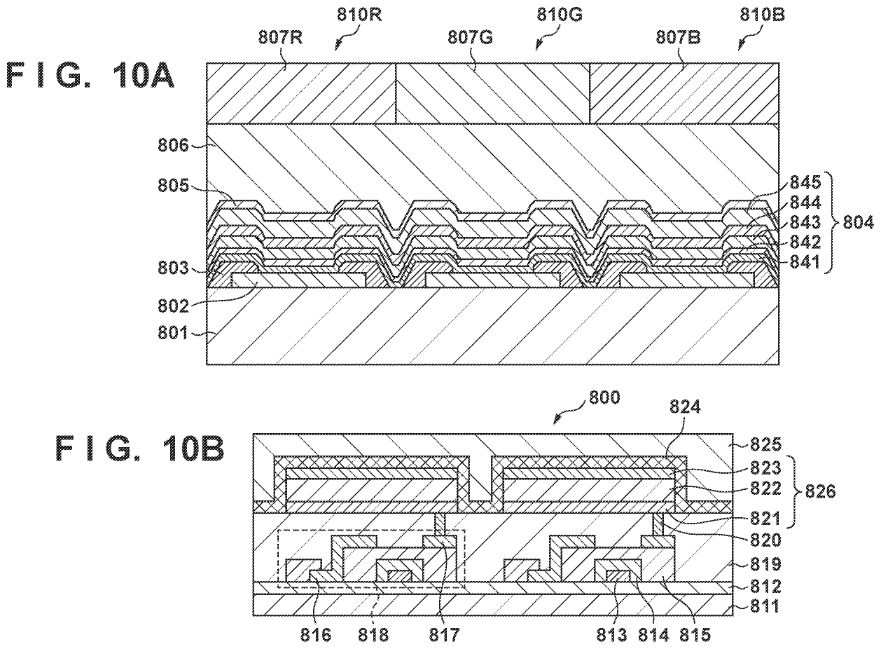

Here, application examples in which the light emitting device 100 according to this embodiment is applied to an image forming device, a display device, a photoelectric conversion device, an electronic apparatus, an illumination device, a moving body, and a wearable device will be described here with reference to FIGS. 10A to 18B. The description will be given assuming that, for example, an organic light emitting element such as an organic EL element using an organic electroluminescence (EL) as the light emitting layer 118 is arranged in the pixel 134 arranged in the pixel portion of the light emitting device 100. Details of each component arranged in the pixel portion including the pixel 134 of the light emitting device 100 described above will be described first, and the application examples will be described after that.

### Arrangement of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case in which a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of detects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in an arrangement including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular weight material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this arrangement, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 10A shows an example of a pixel as a constituent element of the above-described pixel portion. The pixel includes sub-pixels 810 (pixels 134). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A display device 800 (corresponding to the above-described light emitting device 100) shown in FIG. 10B is provided with an organic light emitting element 826 and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 10B. That is, one of the anode and cathode and one of the source electrode and drain electrode of the TFT are electrically connected. The TFT indicates a thin-film transistor.

In the display device 800 shown in FIG. 10B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 10B but may be used as another switching element.

The transistor used in the display device 800 shown in FIG. 10B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 10B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

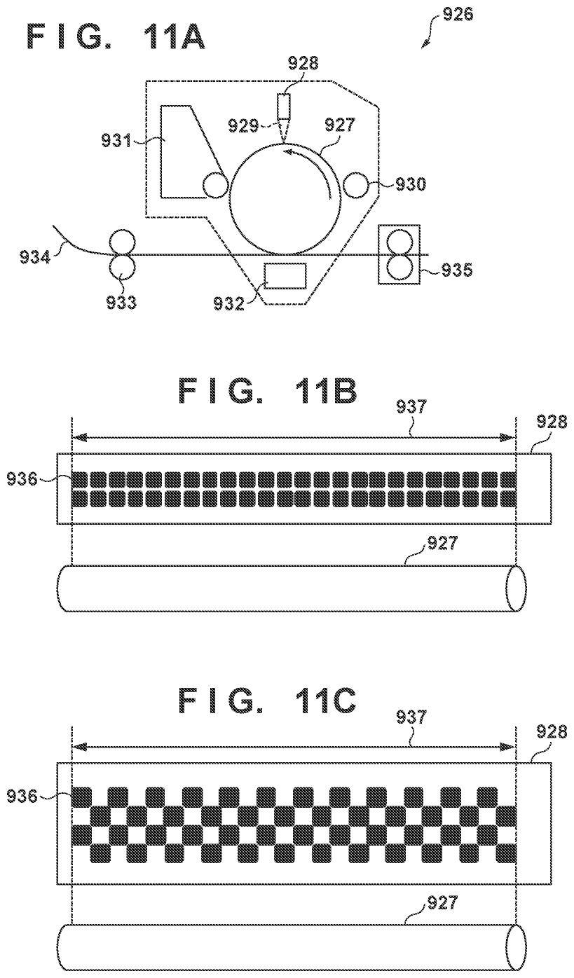

FIGS. 11A to 11C are schematic views showing an example of an image forming device using the light emitting device 100 of this embodiment. An image forming device 926 shown in FIG. 11A includes a photosensitive member 927, an exposure light source 928, a developing unit 931, a charging unit 930, a transfer device 932, a conveyance unit 933 (a conveyance roller in the arrangement shown in FIG. 11A), and a fixing device 935.

Light 929 is emitted from the exposure light source 928, and an electrostatic latent image is formed on the surface of the photosensitive member 927. The light emitting device 100 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 11B and 11C is a schematic view showing a form in which a plurality of light emitting units 936 are arranged in the exposure light source 928 along the longitudinal direction of a long substrate. The light emitting device 100 can be applied to each of the light emitting units 936. That is, the plurality of pixels 134 arranged in the pixel portion are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 11B shows a form in which the light emitting units 936 are arranged along the long-axis direction of the photosensitive member 927. FIG. 11C shows a form, which is a modification of the arrangement of the light emitting units 936 shown in FIG. 11B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 11C can be referred to as, for example, an arrangement in a grid pattern, an arrangement in a staggered pattern, or an arrangement in a checkered pattern.

FIG. 12 is a schematic view showing an example of the display device using the light emitting device 100 of this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 100 can be applied to the display panel 1005. The pixels 134 arranged in the pixel portion of the light emitting device 100 functioning as the display panel 1005 operates in a state in which they are connected to the active elements such as transistors arranged on the circuit board 1007.

The display device 1000 shown in FIG. 12 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

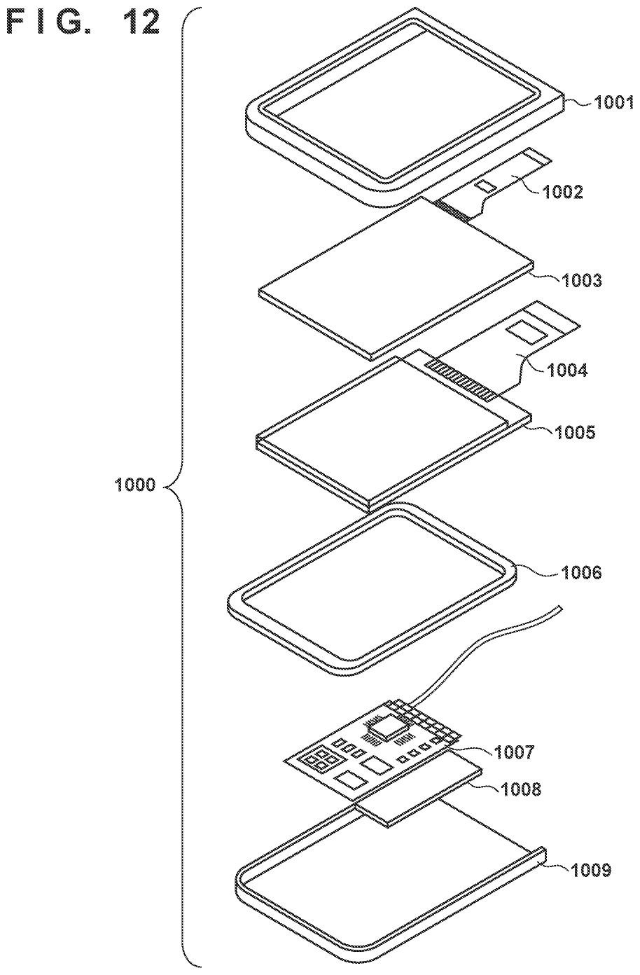

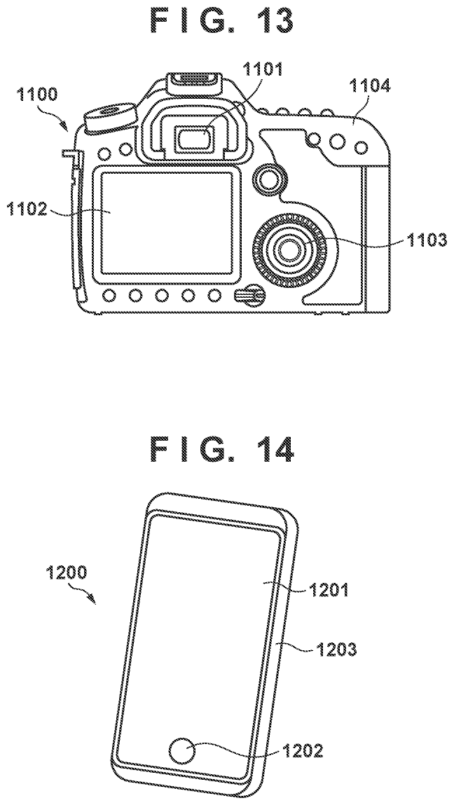

FIG. 13 is a schematic view showing an example of the photoelectric conversion device using the light emitting device 100 of this embodiment. A photoelectric conversion device 1100 can include a viewfinder 1101, a rear display 1102, an operation unit 1103, and a housing 1104. The photoelectric conversion device 1100 can also be called an image capturing device. The light emitting device 100 according to this embodiment can be applied to the viewfinder 1101 or the rear display 1102 as a display unit. In this case, the pixel portion including the pixels 134 of the light emitting device 100 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting device 100 in which the pixel 134 including the light emitting element using the organic light emitting material such as an organic EL element is arranged in the pixel portion may be used for the viewfinder 1101 or the rear display 1102. This is so because the organic light emitting material has a high response speed. The light emitting device 100 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 100 may be applied to a display unit of an electronic apparatus. At this time, the display unit can have both a display function and an operation function. Examples of the portable terminal are a portable phone such as a smartphone, a tablet, and a head mounted display.

FIG. 14 is a schematic view showing an example of an electronic apparatus using the light emitting device 100 of this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 100 according to this embodiment can be applied to the display unit 1201.

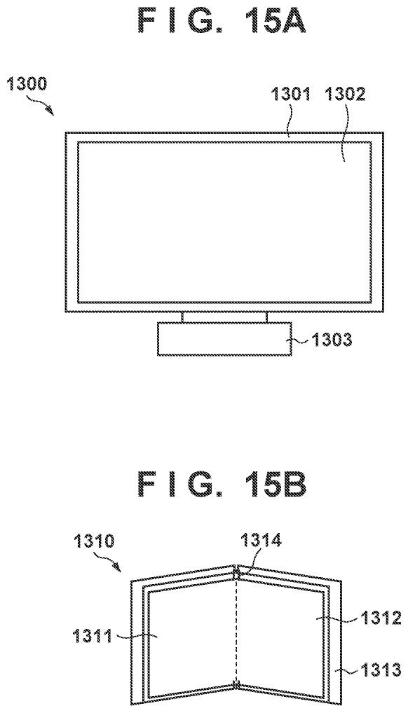

FIGS. 15A and 15B are schematic views showing examples of the display device using the light emitting device 100 of this embodiment. FIG. 15A shows a display device such as a television monitor or a PC monitor. A display device 1300 includes a frame 1301 and a display unit 1302. The light emitting device 100 according to this embodiment can be applied to the display unit 1302. The display device 1300 can include a base 1303 that supports the frame 1301 and the display unit 1302. The base 1303 is not limited to the form shown in FIG. 15A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 15B is a schematic view showing another example of the display device using the light emitting device 100 of this embodiment. A display device 1310 shown in FIG. 15B can be folded, and is a so-called foldable display device. The display device 1310 includes a first display unit 1311, a second display unit 1312, a housing 1313, and a bending point 1314. The light emitting device 100 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

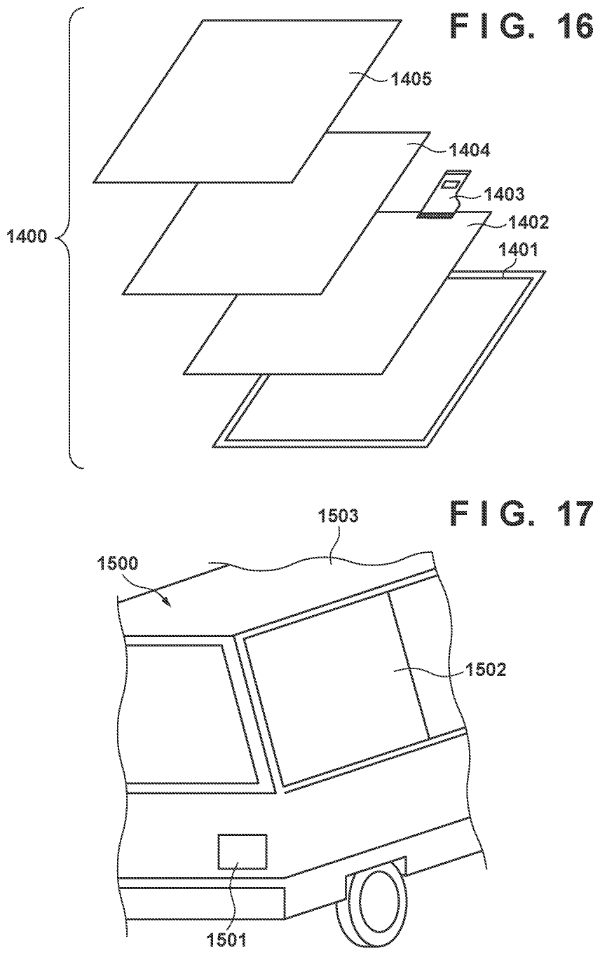

FIG. 16 is a schematic view showing an example of the illumination device using the light emitting device 100 of this embodiment. An illumination device 1400 can include a housing 1401, a light source 1402, a circuit board 1403, an optical film 1404, and a light diffusing unit 1405. The light emitting device 100 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 100 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 17 is a schematic view of an automobile having a taillight as an example of a vehicle lighting appliance using the light emitting device 100 of this embodiment. An automobile 1500 has a taillight 1501, and can have a form in which the taillight 1501 is turned on when performing a braking operation or the like. The light emitting device 100 of this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 100 according to this embodiment can be applied to the taillight 1501. The taillight 1501 can include a protection member for protecting the light emitting device 100 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 100 according to this embodiment may be used. In this case, the constituent materials of the electrodes and the like of the light emitting device 100 are formed by transparent members.

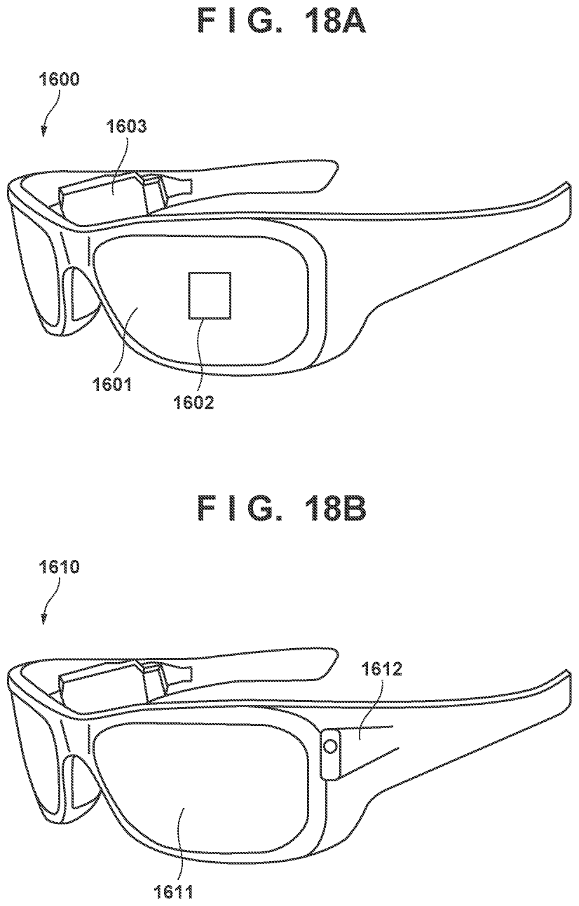

Further application examples of the light emitting device 100 according to this embodiment will be described with reference to FIGS. 18A and 18B. The light emitting device 100 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 18A. An image capturing device 1602 such as a CMOS sensor or an SPAD is provided on the surface side of a lens 1601 of the glasses 1600. In addition, the light emitting device 100 according to this embodiment is provided on the back surface side of the lens 1601.

The glasses 1600 further include a control device 1603. The control device 1603 functions as a power supply that supplies electric power to the image capturing device 1602 and the light emitting device 100 according to each embodiment. In addition, the control device 1603 controls the operations of the image capturing device 1602 and the light emitting device 100. An optical system configured to condense light to the image capturing device 1602 is formed on the lens 1601.

Glasses 1610 (smartglasses) according to one application example will be described with reference to FIG. 18B. The glasses 1610 include a control device 1612, and an image capturing device corresponding to the image capturing device 1602 and the light emitting device 100 are mounted on the control device 1612. The image capturing device in the control device 1612 and an optical system configured to project light emitted from the light emitting device 100 are formed in a lens 1611, and an image is projected to the lens 1611. The control device 1612 functions as a power supply that supplies electric power to the image capturing device and the light emitting device 100, and controls the operations of the image capturing device and the light emitting device 100. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 according to the embodiment of the present disclosure can include an image capturing device including a light receiving element, and control a displayed image based on the line-of-sight information of the user from the image capturing device.

More specifically, the light emitting device 100 decides a first visual field region at which the user is gazing and a second visual field region other than the first visual field region based on the line-of-sight information. The first visual field region and the second visual field region may be decided by the control device of the light emitting device 100, or those decided by an external control device may be received. In the display region of the light emitting device 100, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 100, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 100, the image capturing device, or an external device. If the external device holds the AI program, it is transmitted to the light emitting device 100 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-056358, filed Mar. 30, 2023, which is hereby incorporated by reference herein in its entirety.

What is claimed is:

1. A semiconductor device comprising: a substrate; a pad used to connect an external terminal; an interlayer insulating film, which is arranged between a main surface of the substrate and the pad and where a wiring pattern is arranged; and an insulating film arranged so as to cover a peripheral portion of the pad, wherein
an opening portion configured to connect the pad to the external terminal is provided in the insulating film,
the pad and the wiring pattern are electrically connected via a plug in contact with both the pad and the wiring pattern, and
in an orthogonal projection with respect to the main surface, the plug is arranged outside the opening portion.

2. The device according to claim 1, wherein
the plug is in contact with the pad in the peripheral portion.

3. The device according to claim 1, wherein
the pad and the wiring pattern contain materials different from each other.

4. The device according to claim 1, wherein
a thickness of the pad is smaller than a thickness of the wiring pattern.

5. The device according to claim 1, wherein
the pad and the plug contain materials different from each other.

6. The device according to claim 1, wherein
the plug contains a refractory metal.

7. The device according to claim 1, wherein
the interlayer insulating film is formed by a plurality of interlayer insulating layers stacked on each other, and
among the plurality of interlayer insulating layers, interlayer insulating layers arranged between the pad and the wiring pattern include at least two interlayer insulating layers containing materials different from each other.

8. The device according to claim 7, wherein
the plurality of interlayer insulating layers include an interlayer insulating layer having a lower dielectric constant than silicon oxide.

9. The device according to claim 1, wherein
the pad is electrically connected to the external terminal via a conductive film arranged in the opening portion.

10. The device according to claim 9, wherein
in the orthogonal projection with respect to the main surface, the external terminal includes a portion overlapping the plug.

11. The device according to claim 9, wherein
in the orthogonal projection with respect to the main surface, the conductive film includes a portion in contact with the insulating film outside the opening portion.

12. The device according to claim 1, wherein
a plurality of wiring layers including a wiring layer where the wiring pattern is arranged are arranged in the interlayer insulating film, and
the wiring pattern is arranged in the wiring layer closest to the pad among the plurality of wiring layers.

13. The device according to claim 1, wherein
a plurality of wiring layers including a wiring layer where the wiring pattern is arranged are arranged in the interlayer insulating film,
the wiring pattern is set as a first wiring pattern, and the plug is set as a first plug,
the plurality of wiring layers include a first wiring layer where the first wiring pattern is arranged, and a second wiring layer which is arranged between the first wiring layer and the main surface and where a second wiring pattern is arranged,
the first wiring pattern and the second wiring pattern are electrically connected via a second plug in contact with both the first wiring pattern and the second wiring pattern, and
the first plug is thinner than the second plug.

14. The device according to claim 1, wherein
the insulating film is formed by a plurality of insulating layers stacked on each other, and
the plurality of insulating layers include insulating layers containing materials different from each other.

15. The device according to claim 1, further comprising a plurality of pixels each including a light emitting layer arranged on the main surface.

16. The device according to claim 14, further comprising a plurality of pixels each including a light emitting layer arranged on the main surface,
wherein each of the plurality of pixels is covered with at least one insulating layer of the plurality of insulating layers.

17. The device according to claim 16, wherein
each of the plurality of pixels is covered with an insulating layer farthest from the main surface among the plurality of insulating layers.

18. The device according to claim 16, wherein
each of the plurality of pixels includes a reflection layer arranged between the light emitting layer and the main surface,
the plurality of insulating layers include an optical adjustment layer arranged between the reflection layer and the light emitting layer in each of the plurality of pixels, and
the plurality of pixels include a first pixel and a second pixel different from each other in a thickness of the optical adjustment layer.

19. The device according to claim 18, wherein
the reflection layer is a conductive pattern arranged in the same wiring layer as the pad.

20. A display device comprising the semiconductor device according to claim 15, and an active element connected to the semiconductor device.

21. A photoelectric conversion device comprising an optical unit including a plurality of lenses, an image sensor configured to receive light having passed through the optical unit, and a display unit configured to display an image,
wherein the display unit displays an image captured by the image sensor, and includes the semiconductor device according to claim 15.

22. An electronic apparatus comprising a housing provided with a display unit, and a communication unit provided in the housing and configured to perform external communication,
wherein the display unit includes the semiconductor device according to claim 15.

23. An illumination device comprising a light source, and at least one of a light diffusing unit and an optical film,
wherein the light source includes the semiconductor device according to claim 15.

24. A moving body comprising a main body, and a lighting appliance provided in the main body,
wherein the lighting appliance includes the semiconductor device according to claim 15.

25. A method of manufacturing a semiconductor device comprising: a substrate; a pad used to connect an external terminal; an interlayer insulating film, which is arranged between a main surface of the substrate and the pad and where a wiring pattern is arranged; and an insulating film arranged so as to cover a peripheral portion of the pad, wherein
the pad and the wiring pattern are electrically connected via a plug in contact with both the pad and the wiring pattern,
the method comprises providing, in the insulating film, an opening portion configured to connect the pad to the external terminal, and
in an orthogonal projection with respect to the main surface, the plug is arranged outside the opening portion.

26. The method according to claim 25, wherein
the pad is electrically connected to the external terminal by pressure-bonding via a conductive film arranged in the opening portion.
